(19) United States
(12) Patent Application Publication
(10) Pub. No.: US 2026/0082918 A1
(43) Pub. Date: Mar. 19, 2026

(54) PACKAGE STRUCTURE

(71) Applicant: Advanced Semiconductor Engineering, Inc., Kaohsiung (TW)

(72) Inventors: Cheng-Lin HO, Kaohsiung (TW); Chih-Cheng LEE, Kaohsiung (TW)

(73) Assignee: Advanced Semiconductor Engineering, Inc., Kaohsiung (TW)

(21) Appl. No.: 18/885,468

(22) Filed: Sep. 13, 2024

(51) Int. Cl. H01L 23/00; H01L 23/31; H01L 23/522

(52) U.S. Cl. CPC H10W 42/121; H10W 20/40; H10W 74/111; H10W 72/877; H10W 90/724; H10W 90/734

(57) ABSTRACT

A package structure is provided. The package structure includes an electronic component and a reinforcement element. The electronic component has an active surface, a backside surface opposite to the active surface, and a lateral surface extending between the active surface and the backside surface. The electronic component includes a device layer closer to the active surface than to the backside surface. The reinforcement element contacts the backside surface and is configured to reduce the formation of a crack in the electronic component during a bonding operation.

### BACKGROUND

### 1. Technical Field

The present disclosure relates generally to a package structure.

### 2. Description of the Related Art

Currently, the thickness of a wafer in a wafer level chip scale package (WLCSP) may be increased by adding a dummy silicon layer for warpage control. However, adhesion between the dummy silicon layer and the wafer is relatively poor. For example, when a dummy silicon layer is adhered directly to a wafer, delamination may occur when bonding surfaces are not sufficiently planarized. If an extra adhesive is applied to attach a dummy silicon layer to a wafer, it can lead to delamination or even cracks because of uneven stress at the bonding interface.

### SUMMARY

In one or more arrangements, a package structure includes an electronic component and a reinforcement element. The electronic component has an active surface, a backside surface opposite to the active surface, and a lateral surface extending between the active surface and the backside surface. The electronic component includes a device layer closer to the active surface than to the backside surface. The reinforcement element contacts the backside surface and is configured to reduce the formation of a crack in the electronic component during a bonding operation.

In one or more arrangements, a package structure includes a substrate, an electronic component, and an encapsulant. The electronic component is disposed over the substrate and has an active surface, a backside surface opposite to the active surface, and a lateral surface extending between the active surface and the backside surface. The encapsulant is disposed on the backside surface of the electronic component without extending over the lateral surface of the electronic component.

In one or more arrangements, a package structure includes a substrate, an electronic component, a warpage control element, and a protective element. The electronic component is disposed over the substrate and has an active surface, a backside surface opposite to the active surface, and a lateral surface extending between the active surface and the backside surface. The warpage control element is adhered to the backside surface of the electronic component and is configured to reduce the warpage of the package structure. The protective element encapsulates the electronic component and the warpage control element.

### BRIEF DESCRIPTION OF THE DRAWINGS

Aspects of the present disclosure are better understood from the following detailed description when read with the accompanying drawings. It is noted that various features may not be drawn to scale, and the dimensions of the various features may be arbitrarily increased or reduced for clarity of discussion.

FIG. 1 is a cross-section of a package structure in accordance with some arrangements of the present disclosure.

FIG. 2A is a cross-section of a portion of a package structure in accordance with some arrangements of the present disclosure.

FIG. 2B is a cross-section of a portion of a package structure in accordance with some arrangements of the present disclosure.

FIG. 3A is a cross-section of a package structure in accordance with some arrangements of the present disclosure.

FIG. 3B is a cross-section of a package structure in accordance with some arrangements of the present disclosure.

FIG. 3C is a cross-section of a package structure in accordance with some arrangements of the present disclosure.

FIG. 4A to FIG. 4K illustrate various stages of an exemplary method of forming a package structure in accordance with some arrangements of the present disclosure.

FIG. 5 illustrates one or more stages of an exemplary method of forming a package structure in accordance with some arrangements of the present disclosure.

Common reference numerals are used throughout the drawings and the detailed description to indicate the same or similar elements. The present disclosure will be more apparent from the following detailed description taken in conjunction with the accompanying drawings.

### DETAILED DESCRIPTION

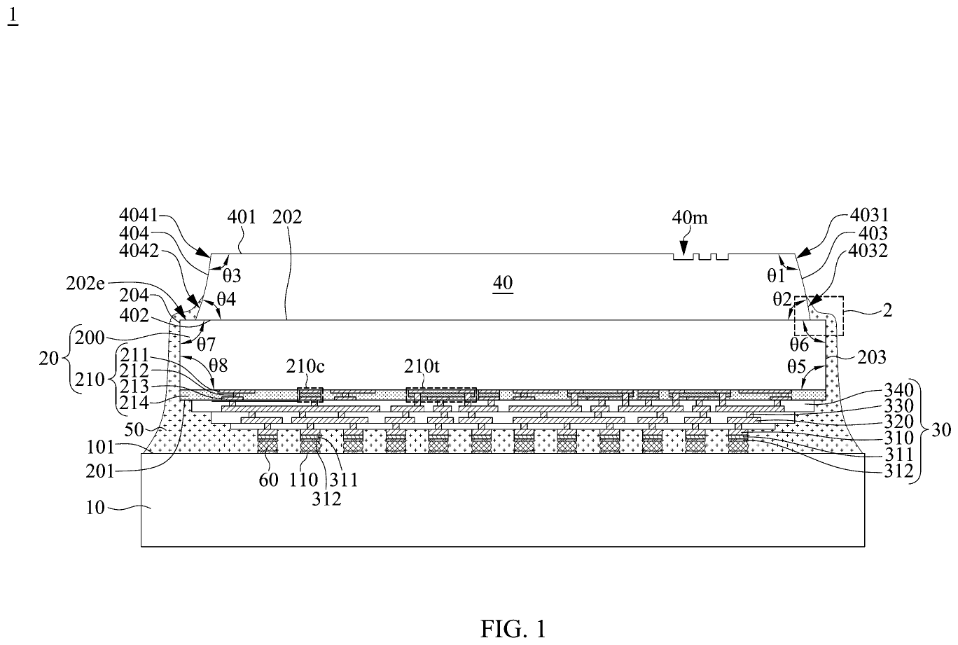

FIG. 1 is a cross-section of a package structure 1 in accordance with some arrangements of the present disclosure. The package structure 1 may include a substrate 10, an electronic component 20, a redistribution layer (RDL) 30, a warpage control element 40, a protective element 50, and electrical contacts 60. In some arrangements, the package structure 1 includes or is applied in a wafer level chip scale package (WLCSP).

The substrate 10 may include, for example, a printed circuit board, such as a paper-based copper foil laminate, a composite copper foil laminate, or a polymer-impregnated glass-fiber-based copper foil laminate. The substrate 10 may include an interconnection structure, such as a plurality of conductive traces and/or a plurality of conductive vias. In some arrangements, the substrate 10 includes a ceramic material, a metal plate, an organic substrate, or a leadframe. In some arrangements, the substrate 10 may include a two-layer substrate which includes a core layer and a conductive material and/or structure disposed on an upper surface and a bottom surface of the substrate 10. The conductive material and/or structure may include a plurality of conductive traces. In some arrangements, the substrate 10 includes conductive pads 110 exposed from a surface 101 of the substrate 10.

The electronic component 20 may be disposed over the substrate 10. The electronic component 20 may have an active surface 201, a backside surface 202 opposite to the active surface 201, and lateral surfaces 203 and 204 extending between the active surface 201 and the backside surface 202. In some arrangements, the electronic component 20 includes a base layer 200 and a device layer 210 disposed or formed on the base layer 200. The base layer 200 may be or include a semiconductor substrate layer, e.g., a silicon layer. In some arrangements, the device layer 210 includes conductive layers 211 and 213, conductive vias 212, and a dielectric structure 214 encapsulating the conductive layers 211 and 213 and the conductive vias 212. The dielectric structure 214 may include a plurality of dielectric layers. The device layer 210 may be referred to as an active layer or a circuit layer. The device layer 210 may include one or more active elements, one or more passive elements, or a combination thereof. For example, the active layer 210 may include one or more transistor structures 210t, one or more capacitor structures 210c, or other applicable elements.

The RDL 30 may be connected to the active surface 201 of the electronic component 20. In some arrangements, the RDL 30 is electrically connected to the device layer 210 of the electronic component 20. In some arrangements, the RDL 30 includes conductive pads 310, conductive layers 320, conductive vias 330, and a dielectric structure 340. In some arrangements, the RDL 30 further includes barrier layers 311 and surface protective layers 312. The barrier layers 311 may be disposed or formed on the conductive pads 310, and the surface protective layers 312 may be disposed or formed on the barrier layers 311. The barrier layer 311 may be formed of or include tantalum (Ti), tungsten (W), chromium (Cr), nickel (Ni), gold (Au), tin (Sn), lead (Pb), or a combination thereof. The surface protection layer 312 may be or include nickel/gold (Ni/Au), nickel/cadmium/gold (Ni/Cd/Au), nickel/silver (Ni/Ag), gold (Au), tin (Sn), alloys thereof (e.g., a tin-lead alloy), silver (Ag), electroless nickel electroless palladium immersion gold (ENEPIG), or a combination thereof. In some arrangements, the barrier layer 311 includes a Ni layer, and the surface protection layer 312 includes an Au layer. The conductive layers 320 and the conductive vias 330 may collectively be referred to as a wiring structure. The fan-out design of the wiring structure in the RDL 30 may depend on the arrangements of the elements/conductive features of the device layer 210, thus the RDL 30 may have an asymmetric wiring structure. The dielectric structure 340 may include a plurality of dielectric layers. In some arrangements, the device layer 210 of the electronic component 20 is electrically connected to the substrate 10 through the RDL 30.

The warpage control element 40 may be disposed over or adhered to the backside surface 202 of the electronic component 20. In some arrangements, the warpage control element 40 is connected to the backside surface 202 of the electronic component 20. In some arrangements, the warpage control element 40 directly contacts the backside surface 202 of the electronic component 20 without covering the lateral surfaces 203 and 204 of the electronic component 20. In some arrangements, the warpage control element 40 covers about 80%, 85%, 90% or higher ratio of the backside surface 202 of the electronic component 20. In some arrangements, the warpage control element 40 tapers away from the electronic component 20 in a cross-sectional view perspective. In some arrangements, the warpage control element 40 is or includes an encapsulant. The warpage control element 40 may include an epoxy resin having fillers dispersed therein, a molding compound (e.g., an epoxy molding compound or other molding compound), polyimide (PI), a phenolic compound or material, a polymer material with silicone dispersed therein, or a combination thereof. The warpage control element 40 may be referred to as a protective element and configured to reduce a warpage of the package structure 1. In some arrangements, the warpage control element 40 is configured to reduce a warpage resulted from the asymmetric wiring structure of the RDL 30. In some arrangements, the warpage control element 40 may be referred to as a reinforcement element and configured to reduce formation of one or more cracks in the electronic component 20 during a bonding operation (e.g., a flip-chip bonding operation). The warpage control element 40 may include a material having a hardness or a rigidity less than that of the electronic component 20. The warpage control element 40 may include a thermal curable material that can be cured after being disposed on the electronic component 20 during the wafer-level stage (e.g., before the singulation operation). Thus, the adhesion between the warpage control element 40 and the electronic component 20 can be improved, and formation of voids can be mitigated or prevented to improve the warpage control and further reduce delamination between the warpage control element 40 and the electronic component 20. In some arrangements, the warpage control element 40 may further include fillers in the thermal curable material, and the fillers may be formed of or include a material the same as a material of the base layer 200 of the electronic component 20 to further reduce the contraction of the warpage control element 40 resulted from CTE mismatch between the warpage control element 40 and the electronic component 20.

When there is a need to increase a thickness of a substrate or a wafer in a package, e.g., a WLCSP, several approaches may be used. For example, a dummy silicon layer may be attached directly to the wafer. However, bonding surfaces of the dummy silicon layer and the wafer are required to be relatively smooth, e.g., with a roughness of less than about 5 nm, to generate a sufficient interaction force (e.g., Van der Waals force) for attaching the dummy silicon layer and the wafer. Such relatively high surface smoothness requires performing a chemical mechanical polishing (CMP) operation, which may increase the processing complexity and costs. In addition, attaching the dummy silicon layer to the wafer is equivalent to bonding a rigid layer to another rigid layer, voids may be easily generated at the bonding interface which may lead to delamination, and the alignment of rigid layers are relatively difficult. To solve the above issue, an extra adhesive may be used to attach the dummy silicon layer to the wafer. However, uneven stress may be generated around the bonding interface between the adhesive and the dummy silicon layer and the bonding interface between the adhesive and the wafer. As a result, delamination or even cracks may occur, which decreases the yield of the package structure. Alternatively, if the dummy silicon layer is replaced by a ceramic layer to be attached to the wafer, a high-temperature sintering operation is required to manufacture the ceramic layer before it is bonded to the wafer, and the relatively high hardness or rigidness of the ceramic layer increases the difficulty to process. In addition, if laser cutting is performed on the ceramic layer, it would require vary high power, which increases the manufacturing costs.

According to some arrangements of the present disclosure, the warpage control element 40 including an encapsulant is relatively soft and attached to the relatively rigid base layer 200 of the electronic component 20. Therefore, the issues of difficulty of alignment between rigid layers can be prevented, and CMP operations for forming smooth bonding surfaces of rigid layers can also be omitted, such that the processing complexity and costs can be reduced. In addition, the warpage control element 40 has a relatively good bonding force with the base layer 200 and thus can also serve as an adhesive to attach to the base layer 200. Therefore, an extra adhesive can be omitted. Moreover, the warpage control element 40 including an encapsulant is relatively soft compared to silicon or ceramic, therefore processing on the warpage control element 40 is relatively easy, for example, laser cutting performed on the encapsulant material of the warpage control element 40 requires relatively low power which may reduce the cost.

In addition, according to some arrangements of the present disclosure, the warpage control element 40 including an encapsulant directly contacts the backside surface 202 of the electronic component 20. The warpage control element 40 may be adhered to the base layer 200 of the electronic component 20 by forming the encapsulant of the warpage control element 40 using a molding technique (e.g., transfer molding or compression molding) instead of laminating an encapsulant layer to the base layer 200, and thus the thickness of the warpage control element 40 can be adjusted to any predetermined value simply by adjusting the molding operation. Therefore, the flexibility of increasing or adjusting the overall thickness of the package structure 1 can be increased. Moreover, the warpage control element 40 is configured to adjust the thickness the combined structure of the warpage control element 40 and the electronic component 20, and thus is configured to adjust the thickness of the entire package structure. As such, the structural strength of the electronic component 20 and thereby the entire package structure 1 can be increased, and thus formation of cracks in the electronic component 20 can be reduced or prevented. In addition, the encapsulant material of the warpage control element 40 may be dispensed directly on the backside surface 202 followed by performing a curing operation to form the warpage control element 40, and thus the interaction between the warpage control element 40 and the base layer 200 involves chemical bonding formed by the curing operation. Therefore, the adhesion force between the warpage control element 40 and the base layer 200 of the electronic component 20 can be relatively strong, and thus delamination can be prevented effectively. Furthermore, the relatively soft encapsulant material of the warpage control element 40 may compensate the warpage stress from the electronic component 20 or the asymmetric wiring structure of the RDL 30, and thus it can reduce the warpage of the package structure 1.

Furthermore, according to some arrangements of the present disclosure, the warpage control element 40 covers a relatively large range of the backside surface 202 of the electronic component 20. Therefore, the relatively soft encapsulant material of the warpage control element 40 covering a relatively large range of the electronic component 20 can provide a cushion against external forces from impacts, such that it is can prevent the electronic component 20 from damages caused by the external forces from impacts, e.g., during handling and transportation. Thus, the warpage control element 40 can provide protection for the package structure 1, e.g., for WLCSP. In addition, the relatively soft encapsulant material of the warpage control element 40 can compensate a relatively large range of the warpage stress from the electronic component 20 or the asymmetric wiring structure of the RDL 30, and thus it can reduce the warpage of the package structure 1 more significantly. Furthermore, the protection or the warpage adjustment provided by the warpage control element 40 can be further adjusted or tuned by adjusting the composition of the encapsulant material of the warpage control element 40, and thus the protection and the warpage control provided by the warpage control element 40 can be relatively flexible depending on the needs.

Moreover, according to some arrangements of the present disclosure, the warpage control element 40 directly contacts the backside surface 202 of the electronic component 20 without covering the lateral surfaces 203 and 204 of the electronic component 20. As abovementioned, the encapsulant material of the warpage control element 40 may be adhered to the base layer 200 of the electronic component 20 by using a molding technique instead of aligning an encapsulant layer with the base layer 200 and then laminating the encapsulant layer to the base layer 200. Therefore, the edge of the warpage control element 40 can be defined by the molding operation to be within the range of the backside surface 202 without exceeding edges of the electronic component 20, and thus the issues of difficulty of alignment between rigid layers can be prevented, and the package size can be prevented from being undesirably increased, e.g., in an x-y plane.

The warpage control element 40 may have a surface 401, a surface 402, and lateral surfaces 403 and 404 extending between the surface 401 and the surface 402. In some arrangements, the lateral surface 404 is opposite to the lateral surface 403. In some arrangements, the warpage control element 40 has at least a lateral surface (e.g., at least one of the lateral surfaces 403 and 404) recessed with respect to at least a lateral surface (e.g., at least one of the lateral surfaces 203 and 204) of the electronic component 20. In some arrangements, the lateral surface 403 of the warpage control element 40 is inclined with respect to the active surface 201 of the electronic component 20. In some arrangements, the lateral surface 403 of the warpage control element 40 is inclined with respect to the backside surface 202 of the electronic component 20. In some arrangements, the lateral surface 404 of the warpage control element 40 is inclined with respect to the active surface 201 of the electronic component 20. In some arrangements, the lateral surface 404 of the warpage control element 40 is inclined with respect to the backside surface 202 of the electronic component 20. In some arrangements, the warpage control element 40 includes a mark 40m at the surface 401. In some arrangements, the mark 40m includes one or more recesses recessed from the surface 401.

In some arrangements, the lateral surface 403 of the warpage control element 40 includes a portion 4032 (or a lower portion) adjacent to the electronic component 20 and a portion 4031 (or an upper portion) distal from the electronic component 20. In some arrangements, an angle θ1 defined by the surface 401 and the portion 4031 of the lateral surface 403 of the warpage control element 40 is greater than 90 degrees. In some arrangements, an angle θ2 defined by the backside surface 202 of the electronic component 20 and the portion 4032 of the lateral surface 403 of the warpage control element 40 is less than 90 degrees. In some arrangements, the lateral surface 404 of the warpage control element 40 includes a portion 4042 (or a lower portion) adjacent to the electronic component 20 and a portion 4041 (or an upper portion) distal from the electronic component 20. In some arrangements, an angle θ3 defined by the surface 401 and the portion 4041 of the lateral surface 404 of the warpage control element 40 is greater than 90 degrees. In some arrangements, an angle θ4 defined by the backside surface 202 of the electronic component 20 and the portion 4042 of the lateral surface 404 of the warpage control element 40 is less than 90 degrees.

In some arrangements, the lateral surface 403 includes a curved portion. In some arrangements, the curved portion of the lateral surface 403 includes a convex curved portion. In some arrangements, the lateral surface 403 is or includes a convex curved surface. In some arrangements, the lateral surface 404 includes a curved portion. In some arrangements, the curved portion of the lateral surface 404 includes a concave curved portion. In some arrangements, the lateral surface 404 is or includes a concave curved surface.

In some arrangements, a portion 202e of the backside surface 202 of the electronic component 20 is exposed by the warpage control element 40 and substantially aligned with a bottom surface (e.g., the surface 402) of the warpage control element 40. In some arrangements, the portion 202e of the backside surface 202 is at a peripheral region of the backside surface 202 of the electronic component 20.

In some arrangements, an angle θ5 defined by the active surface 201 and the lateral surface 203 of the electronic components 20 is greater than or less than 90 degrees. In some arrangements, an angle θ8 defined by the active surface 201 and the lateral surface 204 of the electronic components 20 is greater than or less than 90 degrees. The angle θ5 may be the same as or different from the angle θ8. In some arrangements, the angle θ5 and the angle θ8 may be 80 to 100 degrees, 82 to 98 degrees, 85 to 95 degrees, or 88 to 92 degrees. In some arrangements, an angle θ6 defined by the backside surface 202 and the lateral surface 203 of the electronic component 20 is greater than or less than 90 degrees. In some arrangements, an angle θ7 defined by the backside surface 202 and the lateral surface 204 of the electronic component 20 is greater than or less than 90 degrees. The angle θ6 may be the same as or different from the angle θ7. In some arrangements, the angle θ6 and the angle θ7 may be 80 to 100 degrees, 82 to 98 degrees, 85 to 95 degrees, or 88 to 92 degrees. In some arrangements, the angle θ5 and the angle θ8 are closer to 90 degrees than the angle θ1 and the angle θ3 are. In some arrangements, the angle θ6 and the angle θ7 are closer to 90 degrees than the angle θ2 and the angle θ4 are.

The protective element 50 may be disposed over the substrate 10 and encapsulate the RDL 30. In some arrangements, the protective element 50 encapsulates the electronic component 20 and the warpage control element 40. In some arrangements, the protective element 50 covers the lateral surfaces 203 and 204 and the portion 202e of the backside surface 202 of the electronic component 20. In some arrangements, the protective element 50 further covers a portion of the lateral surfaces 403 and 404 of the warpage control element 40. The protective element 50 may include an underfill, which may include an epoxy resin, a molding compound (e.g., an epoxy molding compound or other molding compound), PI, a phenolic compound or material, a polymer material with silicone dispersed therein, or a combination thereof. The protective element 50 may be free of fillers.

The electrical contacts 60 may be disposed between the substrate 10 and the RDL 30. In some arrangements, the electrical contacts 60 electrically connect the conductive pads 310 to the conductive pads 110 of the substrate 10. The electrical contacts 60 may include solder balls or solder bumps. In some arrangements, the electrical contacts 60 include controlled collapse chip connection (C4) bumps, a ball grid array (BGA), or a land grid array (LGA).

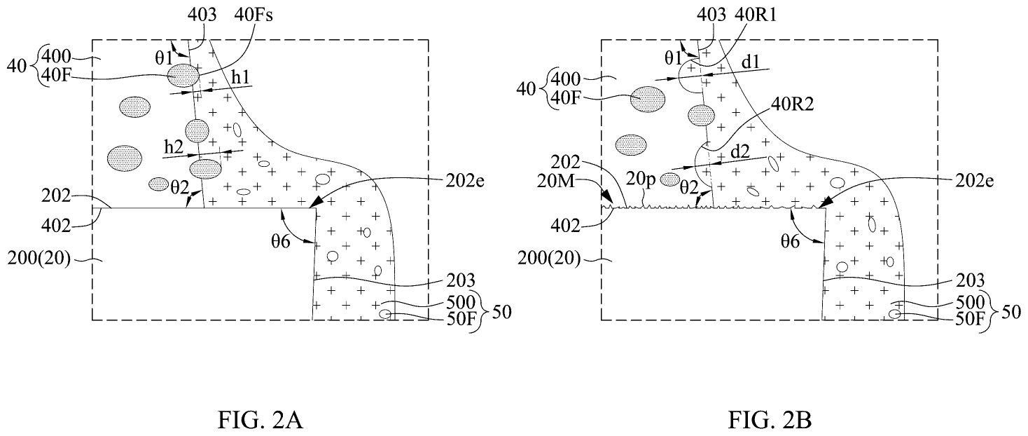

FIG. 2A is a cross-section of a portion of a package structure 1 in accordance with some arrangements of the present disclosure. In some arrangements, FIG. 2A is a cross-section of a portion 2 of the package structure 1 illustrated in FIG. 1 in accordance with some arrangements of the present disclosure.

In some arrangements, the warpage control element 40 includes a resin layer (e.g., the body portion 400) and fillers 40F dispersed in the resin layer (or the body portion 400). The resin layer may be referred to as an encapsulant layer. The fillers 40F may be or include silicon fillers. At two or more of the fillers 40F may have different sizes and/or different shapes.

In some arrangements, one or more of the fillers 40F are exposed by at least one of the lateral surfaces 403 and 404 of the warpage control element 40. In some arrangements, the filler 40F protrudes out of the lateral surface 403 of the warpage control element 40. In some arrangements, at least two of the fillers 40F are protruded out of the lateral surface 403 by different heights. For example, one of the fillers 40F is protruded out of the lateral surface 403 by a height h1, and another one of the fillers 40F is protruded out of the lateral surface 403 by a height h2 greater than the height h1. In some arrangements, the protruded portions of the fillers 40F are encapsulated or covered by the protective element 50. In some arrangements, the filler 40F is partially embedded in the resin layer (or the body portion 400) and partially embedded in the protective element 50 with an interface 40Fs.

In some arrangements, the protective element 50 includes a resin layer 500 and fillers 50F dispersed in the resin layer 500. The fillers 50F may be or include silicon fillers. At two or more of the fillers 50F may have different sizes and/or different shapes. In some arrangements, a size of the fillers 50F is smaller than a size of the fillers 40F.

According to some arrangements of the present disclosure, the fillers 40F that are protruded out of the lateral surface of the warpage control element 40 and protruding into the protective element 50. Therefore, the protruded portions of the fillers 40F can increase the contact area between the warpage control element 40 and the protective element 50, and thus the bonding force between the warpage control element 40 and the protective element 50 can be increased.

FIG. 2B is a cross-section of a portion of a package structure in accordance with some arrangements of the present disclosure. In some arrangements, FIG. 2B is a cross-section of a portion 2 of the package structure 1 illustrated in FIG. 1 in accordance with some arrangements of the present disclosure.

In some arrangements, the warpage control element 40 includes one or more recesses or cavities (e.g., recesses 40R1 and 40R2) recessed from the lateral surface 403 of the warpage control element 40. In some arrangements, a depth d1 of the recess 40R1 is different from a depth d2 of the recess 40R2. In some arrangements, the protective element 50 covers a portion of the lateral surface 403 of the warpage control element 40 and partially extending into one or more of the recesses (e.g., the recesses 40R1). In some arrangements, the protective element 50 includes portions that extend into the recess 40R1 and the recess 40R2, respectively. In some arrangements, the protective element 50 includes portions that extend into different recesses 40R1 and 40R2 by different lengths (e.g., the depths d1 and d2).

In some arrangements, the electronic component 20 includes a microstructure 20M on the backside surface 202 and contacting the warpage control element 40. In some arrangements, the microstructure 20M may be partially covered by the warpage control element 40 and partially covered by the protective element 50. In some arrangements, a roughness (surface roughness (Ra)) of the microstructure 20M is less than a roughness (surface roughness (Ra)) of the lateral surfaces 403 and 404 of the warpage control element 40. In some arrangements, a surface roughness (Ra) of the microstructure 20M is greater than about 0.018 μm. In some arrangements, a surface roughness (Ra) of the microstructure 20M is from about 0.02 μm to about 0.1 μm, from about 0.04 μm to about 0.0.8 μm, or about 0.06 μm. In some arrangements, the microstructure 20M includes a plurality of protrusions 20p. At least two or more of the protrusions 20p may have different sizes and/or shaped. In some arrangements, a size of the protrusion 20p is less than a size of the filler 40F. In some arrangements, a size of the protrusion 20p is less than a size of the recesses 40R1 and 40R2. In some arrangements, a size (e.g., a thickness or a height) of the protrusion 20p may be greater than 0.018 μm. In some arrangements, the size (e.g., the thickness or the height) of the protrusion 20p is from about 0.02 μm to about 0.1 μm, from about 0.04 μm to about 0.0.8 μm, or about 0.06 μm. The microstructure 20M may be configured to increase the bonding strength between the warpage control element 40 and the base layer 200 of the electronic component 20. The microstructure 20M may be configured to increase the bonding strength between the protective element 50 and the base layer 200 of the electronic component 20.

According to some arrangements of the present disclosure, the protective element 50 includes portions that extend into the recess 40R1 and the recess 40R2 of the warpage control element 40. Therefore, the portions of the protective element 50 can interlock with the recesses 40R1 and 40R2 of the warpage control element 40 and thus increase the bonding strength between the warpage control element 40 and the protective element 50.

In addition, according to some arrangements of the present disclosure, the electronic component 20 includes a microstructure 20M on the backside surface 202 and contacting the encapsulant material of the warpage control element 40. Therefore, the protrusions 20p of the microstructure 20M can increase the contact area between the base layer 200 of the electronic component 20 and the warpage control element 40, and thus the bonding force between the electronic component 20 and the warpage control element 40 can be increased. Moreover, the protrusions 20p of the microstructure 20M can also increase the contact area between the base layer 200 of the electronic component 20 and the protective element 50, and thus the bonding force between the electronic component 20 and the protective element 50 can be increased. Moreover, according to some arrangements of the present disclosure, the surface roughness (Ra) is within the aforesaid range, such that the increase in the contact surface is sufficient to increase the bonding force, and the protrusions 20p are not too large or too high to cause delamination or chipping of the electronic component 20.

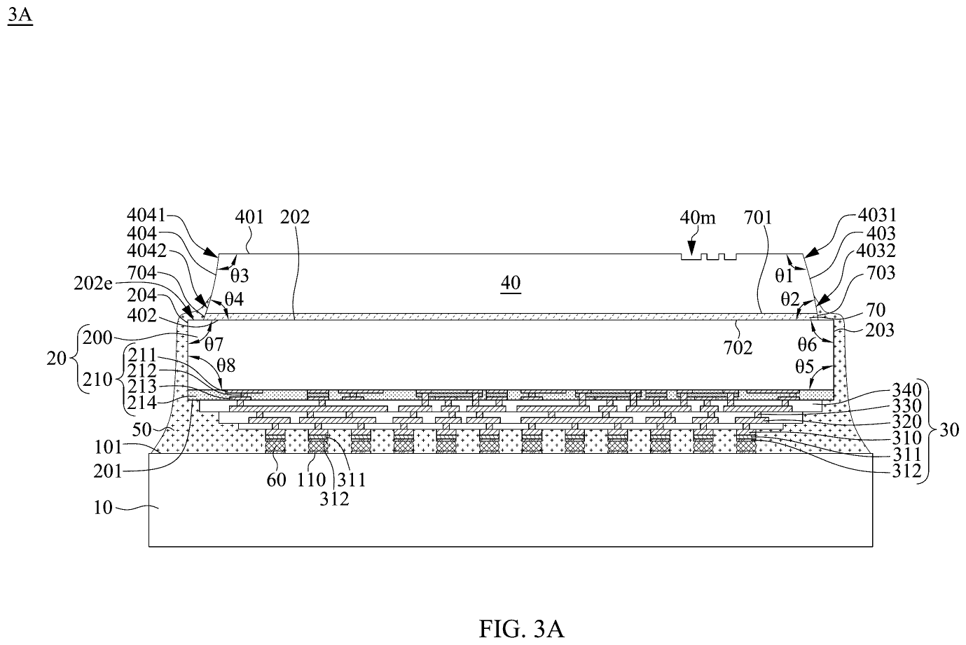

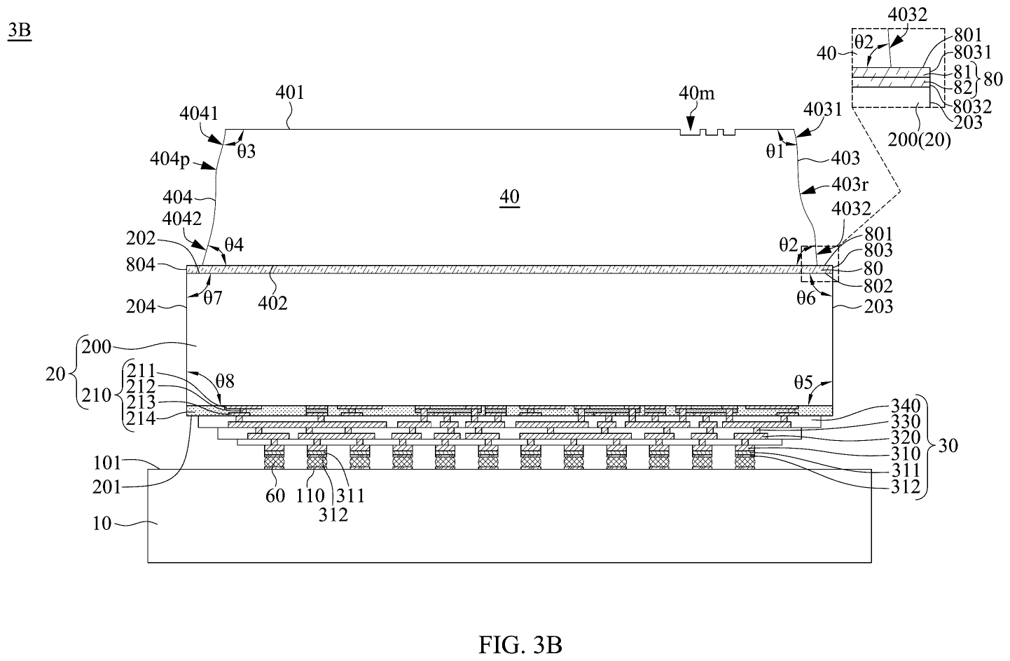

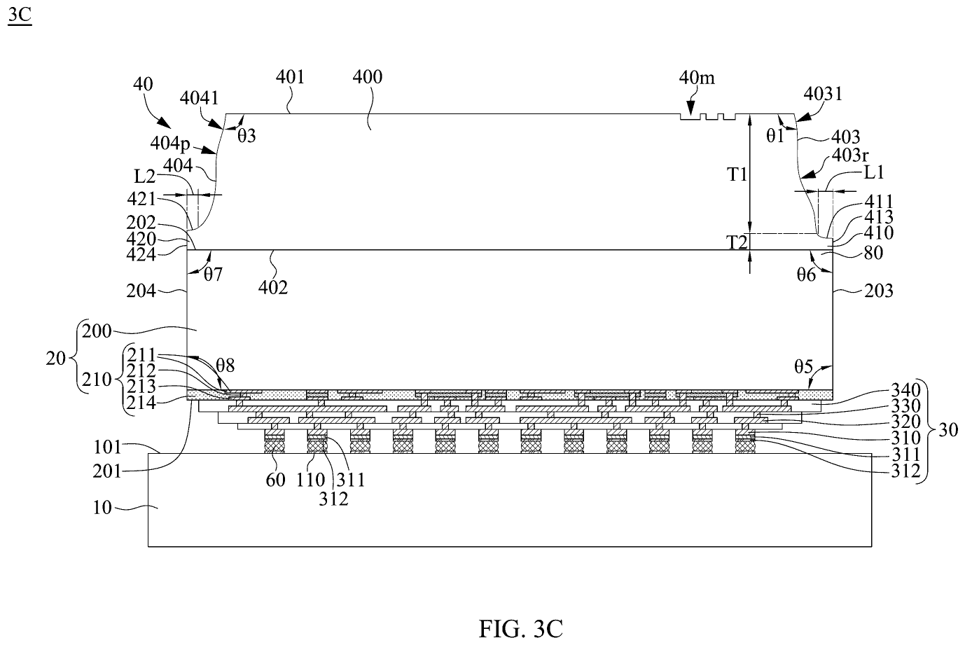

FIG. 3A is a cross-section of a package structure 3A in accordance with some arrangements of the present disclosure. The package structure 3A illustrated in FIG. 3A is similar to the package structure 1 in FIG. 1, and the differences therebetween are described as follows.

In some arrangements, the package structure 3A further includes an adhesive layer 70 between and contacting the warpage control element 40 and the electronic component 20. In some arrangements, the adhesive layer 70 has a top surface 701 contacting the warpage control element 40 and a bottom surface 702 contacting the base layer 200 of the electronic component 20. In some arrangements, the adhesive layer 70 has lateral surfaces 703 and 704 that are substantially aligned with the lateral surfaces 403 and 404, respectively, of the encapsulant. In some arrangements, the lateral surfaces 703 and 704 are recessed with respect to the lateral surfaces 203 and 204, respectively, of the electronic component 20. In some arrangements, the adhesive layer 70 includes a polymer layer. In some arrangements, a thickness of the adhesive layer 70 is from about 20 μm to about 40 μm. The adhesive layer 70 may be formed by coating.

According to some arrangements of the present disclosure, the adhesive layer 70 is between and contacting the warpage control element 40 and the electronic component 20. The adhesive layer 70 includes a polymer material which is compatible with the polymer material of the warpage control element 40, and thus the bonding strength between the warpage control element 40 and the electronic component 20 can be further improved. In addition, the adhesive layer 70 is relatively soft compared to the base layer 200, and thus is can further protect the electronic component 20 from cracking or chipping. Moreover, the adhesive layer 70 may be opaque or black, and thus the mark 40m on the surface 401 of the warpage control element 40 is more distinguishable.

FIG. 3B is a cross-section of a package structure 3B in accordance with some arrangements of the present disclosure. The package structure 3B illustrated in FIG. 3B is similar to the package structure 1 in FIG. 1, and the differences therebetween are described as follows.

In some arrangements, the package structure 3B further includes an adhesive layer 80 between and contacting the warpage control element 40 and the electronic component 20. In some arrangements, the adhesive layer 80 has a top surface 801 contacting the warpage control element 40 and a bottom surface 802 contacting the base layer 200 of the electronic component 20. In some arrangements, the adhesive layer 80 has lateral surfaces 803 and 804 substantially aligned with the lateral surfaces 203 and 204, respectively, of the electronic component 20. In some arrangements, the adhesive layer 80 is partially exposed by the warpage control element 40. In some arrangements, the adhesive layer 80 includes a multi-layered metal film. The adhesive layer 80 may be referred to as an adhesion promoter.

In some arrangements, the adhesive layer 80 includes metal layers 81 and 82. In some arrangements, the metal layer 81 has at least a lateral surface 8031 substantially aligned with the lateral surface 203 of the electronic component 20. In some arrangements, the metal layer 82 has at least a lateral surface 8032 substantially aligned with the lateral surface 203 of the electronic component 20. In some arrangements, the metal layer 81 includes a first metal material, and the metal layer 82 includes a second metal material. A bonding strength or an adhesion force between the first metal material and the warpage control element 40 is greater than a bonding strength or an adhesion force between the second metal material and the warpage control element 40. A bonding strength or an adhesion force between the second metal material and the base layer 200 is greater than a bonding strength or an adhesion force between the first metal material and the base layer 200. The metal layer 81 contacting the warpage control element 40 may include copper (Cu). The metal layer 82 contacting the base layer 200 of the electronic component 20 may include titanium (Ti), aluminum (Al), stainless steel, or a combination thereof. The metal layers may be formed by sputtering.

In some arrangements, the lateral surface 403 of the warpage control element 40 includes a recess 403r. In some arrangements, the lateral surface 404 of the warpage control element 40 includes a protrusion 404p.

According to some arrangements of the present disclosure, the adhesive layer 80 includes a multi-layered metal film and between and contacting the warpage control element 40 and the electronic component 20. With the arrangements of the metal layers in the adhesive layer 80, the bonding strength between the warpage control element 40 and the base layer 200 can be further improved. Therefore, the reliability of the package structure 3B is improved, and the yield is increased.

FIG. 3C is a cross-section of a package structure 3C in accordance with some arrangements of the present disclosure. The package structure 3C illustrated in FIG. 3C is similar to the package structure 1 in FIG. 1, and the differences therebetween are described as follows.

In some arrangements, the warpage control element 40 has multiple upper surfaces opposite to the bottom surface (e.g., the surface 402) and at different elevations. In some arrangements, the warpage control element 40 has surfaces 401, 411, and 421 that are opposite to the surface 402 and at different elevations. In some arrangements, the surfaces 411 and 421 are at elevations between the surface 401 and the surface 402.

In some arrangements, the warpage control element 40 includes a body portion 400 having at least the portion 4031 of the lateral surface 403 and at least the portion 4041 of the lateral surface 404. In some arrangements, the warpage control element 40 further includes a protrusion 410 protruding toward the lateral surface 203 of the electronic component 20 and a protrusion 420 protruding toward the lateral surface 204 of the electronic component 20. In some arrangements, the protrusion 410 has the surface 411 as its top surface, and the protrusion 420 has the surface 421 as its top surface. Top surfaces (e.g., the surfaces 411 and 421) of the protrusions 410 and 420 may be at substantially the same or different elevations. In some arrangements, an extending length L1 of the protrusion 410 is different from an extending length L2 of the protrusion 420. In some arrangements, a thickness T1 of the body portion 400 is greater than a thickness T2 of the protrusion 410.

In some arrangements, the protrusion 410 has a lateral surface 413 substantially aligned with the lateral surface 203 of the electronic component 20. In some arrangements, the protrusion 420 has a lateral surface 424 substantially aligned with the lateral surface 204 of the electronic component 20. In some arrangements, the lateral surface 413 of the protrusion 410 and the lateral surface 403 of the body portion 400 collectively form a lateral surface of the warpage control element 40. In some arrangements, the lateral surface 424 of the protrusion 420 and the lateral surface 404 of the body portion 400 collectively form a lateral surface of the warpage control element 40. In some arrangements, one of the lateral surfaces of the warpage control element 40 includes a first portion (e.g., a lateral surface 413) substantially aligned with the lateral surface 203 of the electronic component 20 and a second portion (e.g., the lateral surface 403) recessed with respect to the first portion. In some arrangements, the other one of the lateral surfaces of the warpage control element 40 includes a first portion (e.g., a lateral surface 424) substantially aligned with the lateral surface 204 of the electronic component 20 and a second portion (e.g., the lateral surface 404) recessed with respect to the first portion.

According to some arrangements of the present disclosure, the protrusions 410 and 420 extend toward edges of the electronic component 20. With the aforesaid design, the warpage control element 40 covers and contacts a relatively large area of the backside surface 202 of the electronic component 20. Therefore, the adhesion between the warpage control element 40 and the electronic component 20 can be improved.

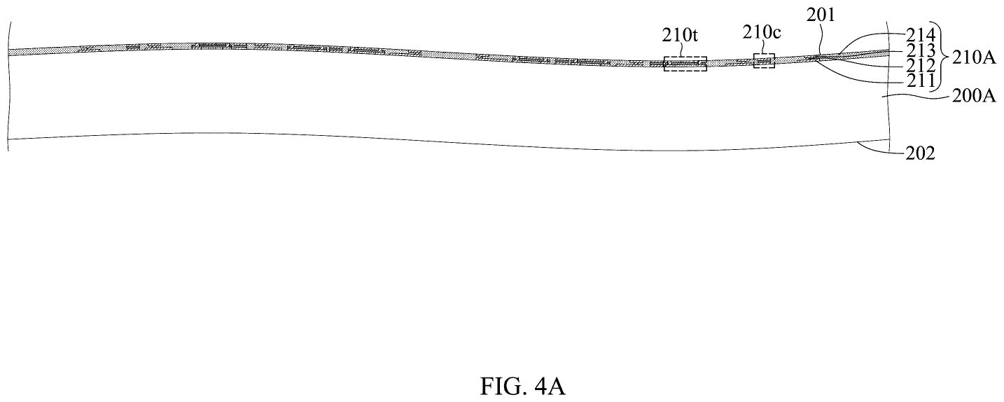

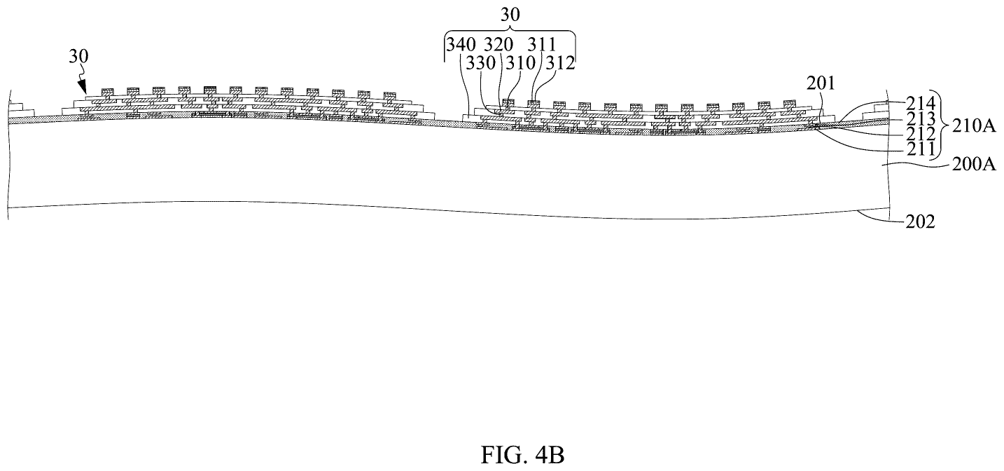

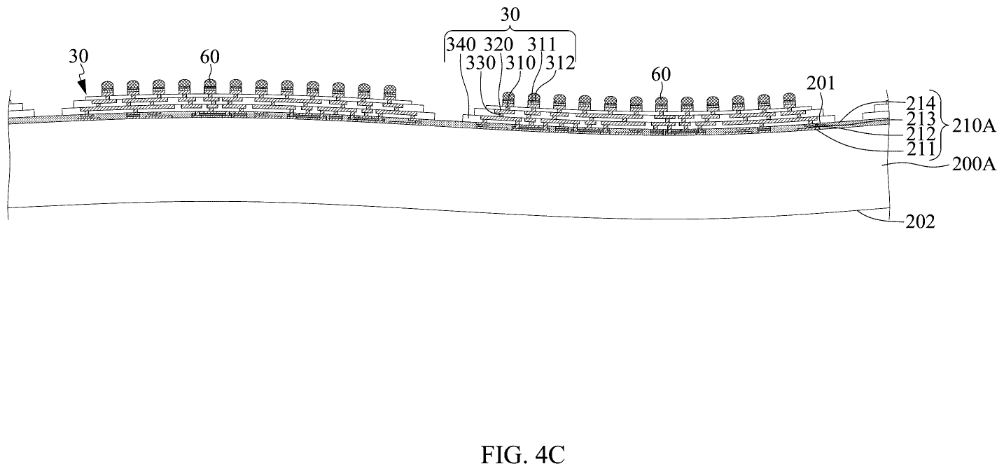

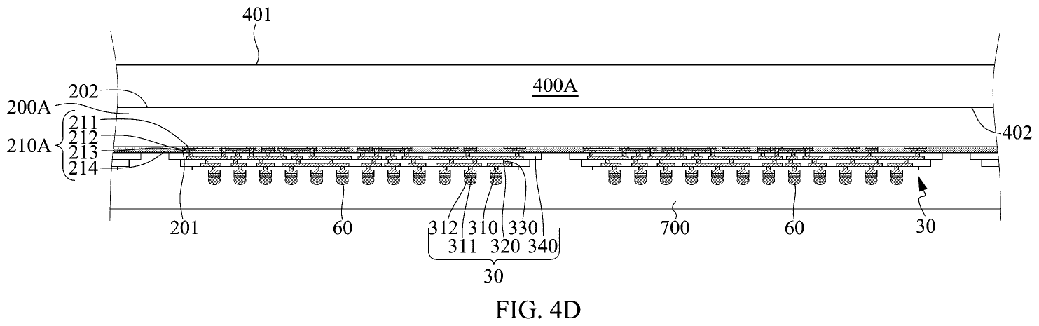

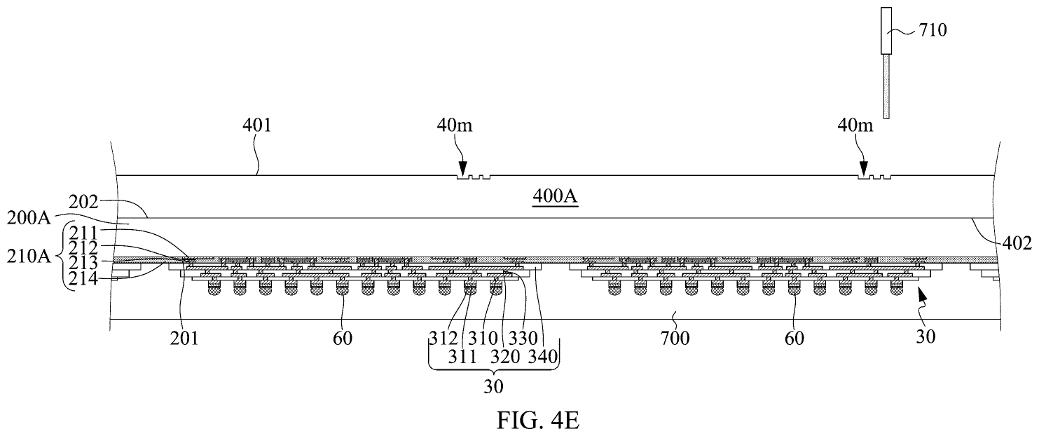

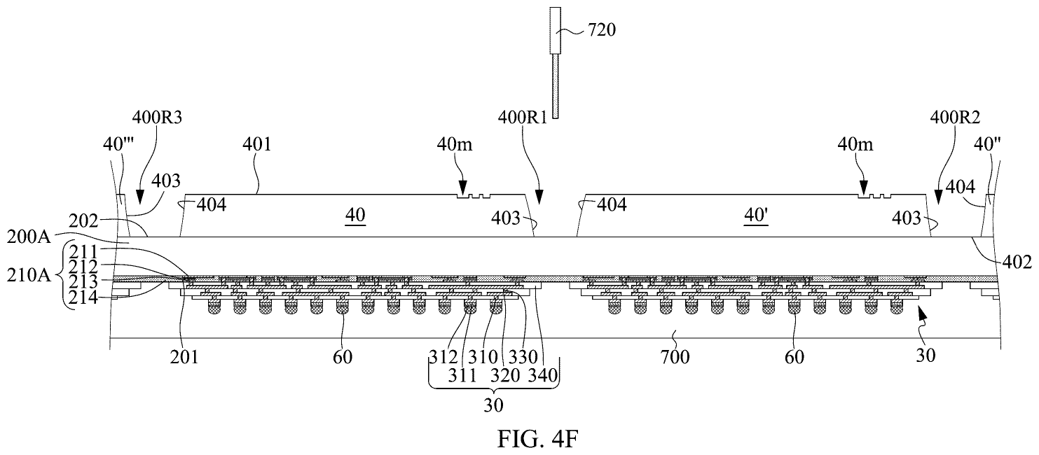

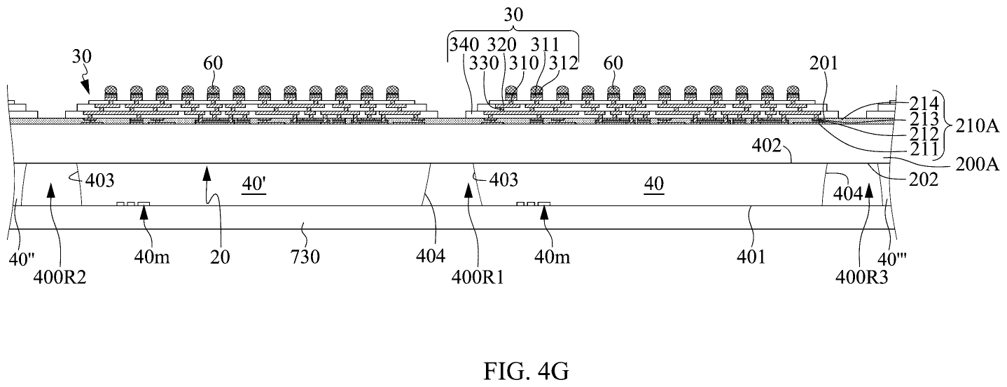

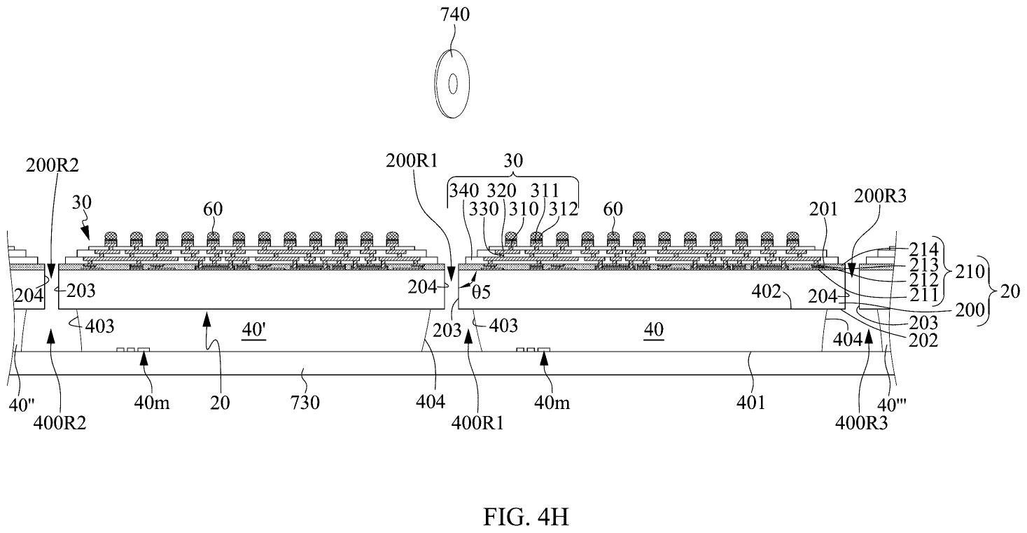

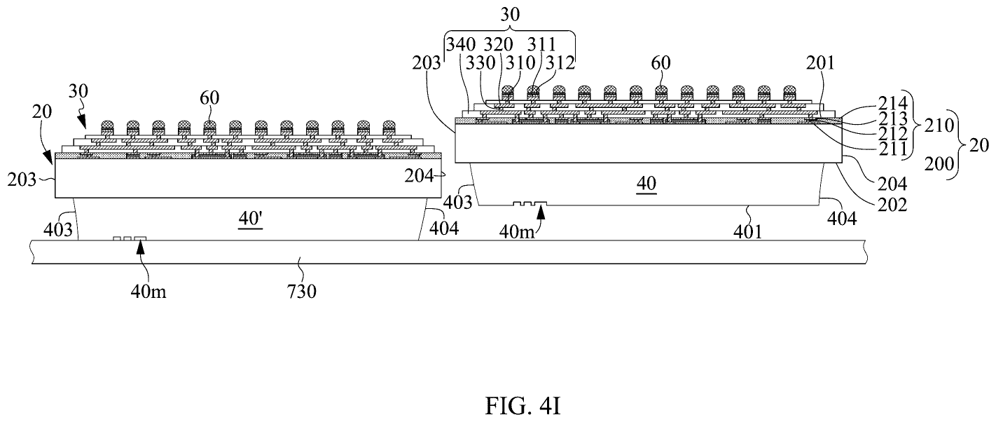

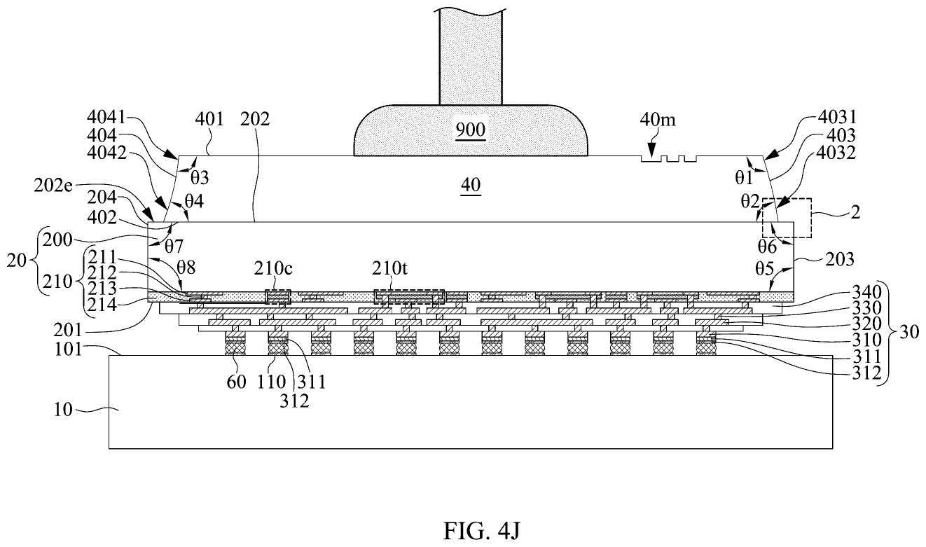

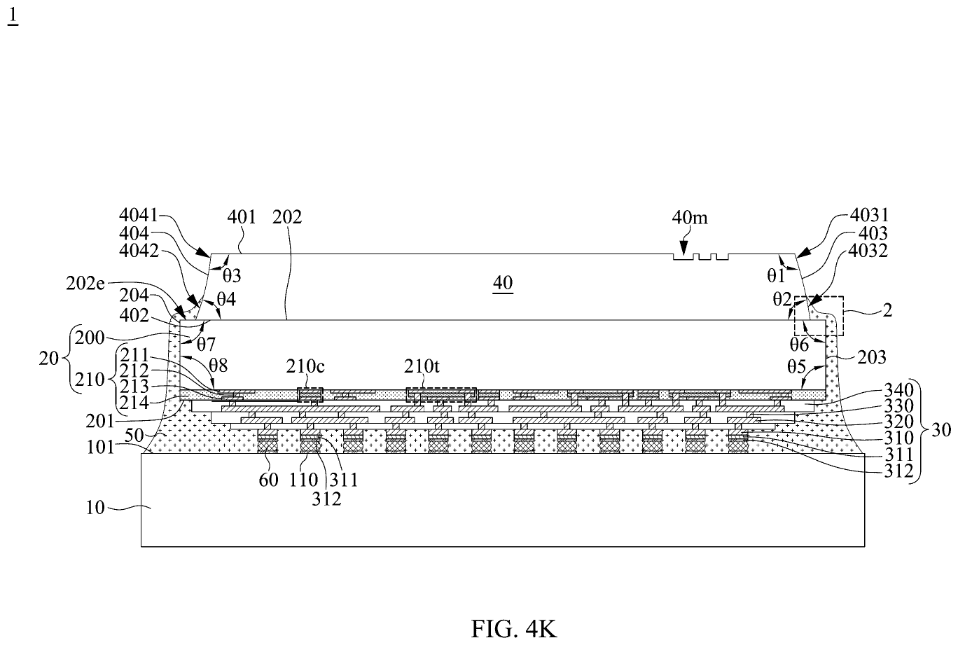

FIG. 4A to FIG. 4J illustrate various stages of an exemplary method of forming a package structure 1 in accordance with some arrangements of the present disclosure.

Referring to FIG. 4A, a wafer level structure including a base layer 200A and a device layer 210A may be provided. The device layer 210A may have an active surface 201, and the base layer 200A may have a backside surface 202. In some arrangements, the device layer 210A includes conductive layers 211 and 213, conductive vias 212, and a dielectric structure 214 encapsulating the conductive layers 211 and 213 and the conductive vias 212. The active layer 210 may include one or more transistor structures 210t, one or more capacitor structures 210c, or other applicable elements. In some arrangements, the wafer level structure as shown in FIG. 4A may have a non-planar structure, e.g., a wavy structure in a cross-sectional view, which may be resulted from the relatively large size of the wafer level structure. In some arrangements, the active surface 201 may be non-planar. As shown in FIG. 4A, the wafer level structure may have a relatively large warpage due to the relatively large area of the active surface 201.

Referring to FIG. 4B, RDLs 30 may be formed over and electrically connected to the device layer 210A. In some arrangements, the RDL 30 includes conductive pads 310, barrier layers 311, surface protective layers 312, conductive layers 320, conductive vias 330, and a dielectric structure 340. In some arrangements, portions of the dielectric structure 214 are exposed by gaps between the RDLs 30. In some arrangements, the conductive layers 211 and 213 and the conductive vias 212 are free from vertically overlapping the gaps between the RDLs 30.

Referring to FIG. 4C, electrical contacts 60 may be formed or disposed over the conductive pads 310.

Referring to FIG. 4D, the structure illustrated in FIG. 4C may be flipped over and disposed on a carrier 700, and an encapsulant layer 400A may be disposed or dispensed over the backside surface 202 of the base layer 200A. The carrier 700 may be a deformable carrier configured to allow the protruded features (e.g., at least the electrical contacts 60) to sink into the carrier 700. In some embodiments, the base layer 200A is supported by the carrier 700, and the RDLs 30 and the electrical contacts 60 are embedded into the carrier 700. In some arrangements, the encapsulant layer 400A is supported by the carrier 700. The encapsulant layer 400A may serve as a warpage control element that reduces the warpage of the wafer level structure illustrated in FIG. 4C, and the structure illustrated in FIG. 4D has a relatively small warpage. In some arrangements, with the encapsulant layer 400A disposed over the backside surface 202 of the base layer 200A, the warpage of the structure illustrated in FIG. 4D is reduced significantly compared with that in FIG. 4C.

Referring to FIG. 4E, marks 40m may be formed on a surface 401 of the encapsulant layer 400A. In some arrangements, a laser device 710 may be used to form the marks 40m on the surface 401. Portions of the encapsulant layer 400A may be removed to form recesses recessed from the surface 401, and the recesses may construct the marks 40m.

Referring to FIG. 4F, portions of the encapsulant layer 400A may be removed to separate the encapsulant layer 400A into a plurality of encapsulants (e.g., warpage control elements 40, 40′, 40″, and 40′″). In some arrangements, the portions are removed by laser cutting to form trenches (e.g., trenches 400R1, 400R2, and 400R3) between the warpage control elements 40, 40′, 40″, and 40′″. In some arrangements, each of the trenches 400R1, 400R2, and 400R3 is formed by a laser cutting operation. In some arrangements, a laser device 720 may be used to form the trenches 400R1, 400R2, and 400R3. In some arrangements, the trenches 400R1, 400R2, and 400R3 have cross-sectional shapes tapering toward the base layer 200A or the surface 402 of the encapsulant layer 400A because the laser cutting operation provides heat from the surface 401 of the encapsulant layer 400A. In some arrangements, portions of the backside surface 202 of the base layer 200A are exposed by the trenches 400R1, 400R2, and 400R3. In some arrangements, at least two or more of the trenches 400R1, 400R2, and 400R3 have different cross-sectional profiles. By varying the power, the waveform, or other conditions under which the laser cuttings are performed, the cross-sectional profiles of the different trenches 400R1, 400R2, and 400R3 may be different. For example, the trench 400R1 is defined by convex lateral surfaces 403 and 404, and the trenches 400R2 and 400R3 are defined by concave lateral surfaces 403 and 404.

Referring to FIG. 4G, the structure illustrated in FIG. 4F may be flipped over and disposed over a tape 730, and the carrier 700 may be removed. In some arrangements, the tape 730 is a dicing tape.

Referring to FIG. 4H, portions of the base layer 200A and portions of the device layer 210A may be removed to separate the base layer 200A into a plurality of base layers 200 and separate the device layer 210A into a plurality of device layers 210 over the base layers 200, so as to form a plurality of electronic components 20. In some arrangements, the portions are removed by mechanical cutting to form gaps (e.g., gaps 200R1, 200R2, and 200R3) between the base layers 200 and between the device layers 210. In some arrangements, each of the gaps 200R1, 200R2, and 200R3 is formed by a mechanical cutting operation. In some arrangements, portions of the dielectric structure 214 and portions of the base layer 200A are removed by the mechanical cutting. In some arrangements, the RDL 30, the conductive pads 310, the conductive layers 320, and the conductive vias 330 are not removed or partially removed by the mechanical cutting. In some arrangements, a cutting device 740 may be used to form the gaps 200R1, 200R2, and 200R3. In some arrangements, the trenches 400R1, 400R2, and 400R3 are connected to the gaps 200R1, 200R2, and 200R3, respectively. In some arrangements, each of the gaps 200R1, 200R2, and 200R3 is defined by lateral surfaces 203 and 204 of the electronic components 20. After the electronic components 20 are formed by separating the base layer 200A and the device layer 210A, a plurality of packages are formed over the tape 730. Because the warpage of the wafer level structure is reduced by the encapsulant layer 400A, the warpage control of the as-formed packages is improved significantly. In some arrangements, the angle θ5 defined by the active surface 201 and the lateral surface 203 of the electronic components 20 is close to 90 degrees, which indicates that the wavy structure illustrated in FIG. 4A has been planarized to reduce, and thus the warpage of the package is relatively small.

According to some arrangements of the present disclosure, the singulation operation is divided into two cutting steps from opposite directions including a laser cutting process from the encapsulant layer 400A and a mechanical cutting process from the base layer 200A. Therefore, the relatively thickness wafer-level structure can be singulated successfully.

In addition, according to some arrangements of the present disclosure, the encapsulant layer 400A is cut by laser followed by the mechanical cutting of the base layer 200A. The encapsulant layer 400A is cut using a non-contact method, e.g., the laser cutting operation, thereby reducing the stress caused by mechanical cutting on the encapsulant layer 400A and even the entire structure. Therefore, warpage of the encapsulant layer 400A can be reduced, and delamination can be further prevented.

Referring to FIG. 4I, an inspection may be performed on the packages, and then a pick-and-place operation may be performed to remove the packages from the tape 730.

Referring to FIG. 4J, the package may be connected to a substrate 10 through the electrical contacts 60. In some arrangements, a compression operation or a thermal operation may be performed to connect the structure to the substrate 10 through the electrical contacts 60. In some arrangements, a bond head 900 may be used to bond the package to the substrate 10. In some arrangements, the encapsulant layer 400A may be configured to reduce the impact or the compression force from the bond head 900 onto the package during the bonding operation so as to reduce damages or formation of cracks. In some arrangements, the package may be connected or bonded to the substrate 10 by flip-chip technique, hybrid-bond technique, or thermal compression bonding (TCB) technique.

Referring to FIG. 4K, a protective element 50 may be disposed or formed to cover the lateral surfaces 203 and 204 of the electronic component 20. As such, the package structure 1 illustrated in FIG. 1 may be formed.

In some arrangements, referring to FIG. 4D and FIG. 3A, a wafer-level polymer adhesive layer may be formed on the backside surface 202, and then the encapsulant layer 400A may be formed on the adhesive layer. Next, operations similar to those illustrated in FIG. 4E may be formed, and then referring to FIG. 4F, the wafer-level adhesive layer may be partially removed along with the removal of the portions of the encapsulant layer 400A to form the adhesive layer 70, as illustrated in FIG. 3A. Next, operations similar to those illustrated in FIGS. 4G to 4J may be performed. As such, the package structure 3A illustrated in FIG. 3A may be formed.

In some arrangements, referring to FIG. 4D and FIG. 3B, a wafer-level multi-layered metal layer may be formed on the backside surface 202, and then the encapsulant layer 400A may be formed on the adhesive layer. Next, operations similar to those illustrated in FIGS. 4E-4G may be formed, and then referring to FIG. 4H, the wafer-level multi-layered metal layer may be partially removed along with the removal of the portions of the encapsulant layer 400A to form the adhesive layer 80, as illustrated in FIG. 3B. Next, operations similar to those illustrated in FIGS. 4H to 4J may be performed. As such, the package structure 3B illustrated in FIG. 3B may be formed.

In some arrangements, referring to FIG. 4F and FIG. 3C, portions of the encapsulant layer 400A may be removed to form trenches 400R1, 400R2, and 400R3 without exposing portions of the backside surface 202. In some arrangements, the encapsulants are not formed during the current stage. Next, operations similar to those illustrated in FIG. 4G may be formed, and then referring to FIG. 4H, the mechanical cutting operations may be performed to form the gaps 200R1, 200R2, and 200R3 and further remove portions of the encapsulant layer 400A to further extend the trenches 400R1, 400R2, and 400R3 to connect to the gaps 200R1, 200R2, and 200R3. As such, referring to FIG. 3C, the lateral surfaces 403 and 404 are formed by laser cutting, and the lateral surfaces 413 and 424 are formed by mechanical cutting. Next, operations similar to those illustrated in FIGS. 4I to 4J may be performed. As such, the package structure 3C illustrated in FIG. 3C may be formed.

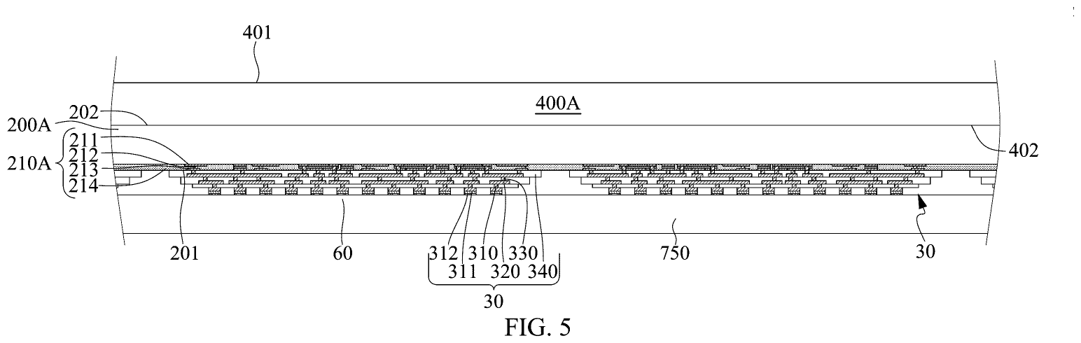

FIG. 5 illustrates one or more stages of an exemplary method of forming a package structure 1 in accordance with some arrangements of the present disclosure.

In some arrangements, operations similar to those illustrated in FIGS. 4A-4B may be performed, and then the structure illustrated in FIG. 4B may be flipped over and disposed on a carrier 750 as illustrated in FIG. 5. In some arrangements, the carrier 750 is or includes a rigid carrier (e.g., glass), the top surface of the structure illustrated in FIG. 4B is relatively planar (e.g., without the electrical contacts 60), and the structure illustrated in FIG. 4B is disposed over and supported by the carrier 750. Next, operations similar to those illustrated in FIGS. 4C-4G may be performed, the carrier 750 may be removed from the RDLs 30, and electrical contacts 60 may be disposed over the conductive pads 310. Next, operations similar to those illustrated in FIGS. 4I to 4J may be performed. As such, the package structure 1 illustrated in FIG. 1 may be formed.

Spatial descriptions, such as “above,” “below,” “up,” “left,” “right,” “down,” “top,” “bottom,” “vertical,” “horizontal,” “side,” “higher,” “lower,” “upper,” “over,” “under,” and so forth, are indicated with respect to the orientation shown in the figures unless otherwise specified. It should be understood that the spatial descriptions used herein are for purposes of illustration only, and that practical implementations of the structures described herein can be spatially arranged in any orientation or manner, provided that the merits of embodiments of this disclosure are not deviated from by such an arrangement.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, a first numerical value can be deemed to be “substantially” the same or equal to a second numerical value if the first numerical value is within a range of variation of less than or equal to ±10% of the second numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, “substantially” perpendicular can refer to a range of angular variation relative to 90° that is less than or equal to ±10°, such as less than or equal to ±5°, less than or equal to ±4°, less than or equal to ±3°, less than or equal to ±2°, less than or equal to ±1°, less than or equal to ±0.5°, less than or equal to ±0.1°, or less than or equal to ±0.05°.

Two surfaces can be deemed to be coplanar or substantially coplanar if a displacement between the two surfaces is no greater than 5 μm, no greater than 2 μm, no greater than 1 μm, or no greater than 0.5 μm. A surface can be deemed to be substantially flat if a displacement between a highest point and a lowest point of the surface is no greater than 5 μm, no greater than 2 μm, no greater than 1 μm, or no greater than 0.5 μm.

As used herein, the singular terms “a,” “an,” and “the” may include plural referents unless the context clearly dictates otherwise.

As used herein, the terms “conductive,” “electrically conductive” and “electrical conductivity” refer to an ability to transport an electric current. Electrically conductive materials typically indicate those materials that exhibit little or no opposition to the flow of an electric current. One measure of electrical conductivity is Siemens per meter (S/m). Typically, an electrically conductive material is one having a conductivity greater than approximately 104 S/m, such as at least 105 S/m or at least 106 S/m. The electrical conductivity of a material can sometimes vary with temperature. Unless otherwise specified, the electrical conductivity of a material is measured at room temperature.

Additionally, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified.

While the present disclosure has been described and illustrated with reference to specific embodiments thereof, these descriptions and illustrations are not limiting. It should be understood by those skilled in the art that various changes may be made and equivalents may be substituted without departing from the true spirit and scope of the present disclosure as defined by the appended claims. The illustrations may not be necessarily drawn to scale. There may be distinctions between the artistic renditions in the present disclosure and the actual apparatus due to manufacturing processes and tolerances. There may be other embodiments of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations of the present disclosure.

What is claimed is:

1. A package structure, comprising:
an electronic component having an active surface, a backside surface opposite to the active surface, and a lateral surface extending between the active surface and the backside surface, the electronic component comprising a device layer closer to the active surface than to the backside surface; and
a reinforcement element contacting the backside surface, wherein the reinforcement element is configured to reduce formation of a crack in the electronic component during a bonding operation.

2. The package structure as claimed in claim 1, further comprising:
a plurality of electrical contacts electrically connecting the electronic component to a substrate; and
a protective element encapsulating the electrical contacts and contacting the reinforcement element.

3. The package structure as claimed in claim 2, wherein the reinforcement element comprises a thermal curable material.

4. The package structure as claimed in claim 3, wherein a lateral surface of the reinforcement element is inclined with respect to the backside surface of the electronic component.

5. The package structure as claimed in claim 4, the lateral surface of the reinforcement element is recessed with respect to the lateral surface of the electronic component.

6. The package structure as claimed in claim 5, wherein the reinforcement element comprises an encapsulant layer and a filler at least partially in the encapsulant layer, wherein the filler is exposed by the lateral surface of the reinforcement element.

7. The package structure as claimed in claim 6, wherein the reinforcement element comprises a first cavity recessed from the lateral surface of the reinforcement element, and the protective element covers a portion of the lateral surface of the reinforcement element and partially extends into the first cavity.

8. The package structure as claimed in claim 1, wherein the reinforcement element has a bottom surface facing the electronic component, a first upper surface opposite to the bottom surface, and a second upper surface at an elevation between the first upper surface and the bottom surface.

9. A package structure, comprising:
a substrate;
an electronic component disposed over the substrate and having an active surface, a backside surface opposite to the active surface, and a lateral surface extending between the active surface and the backside surface; and
an encapsulant disposed on the backside surface of the electronic component without extending over the lateral surface of the electronic component,.

10. The package structure as claimed in claim 9, further comprising a protective element between the electronic component and the substrate, wherein the protective element contacts the electronic component and a lateral surface of the encapsulant.

11. The package structure as claimed in claim 10, wherein the lateral surface of the encapsulant comprises a first portion adjacent to the electronic component and a second portion distal from the electronic component, and an angle defined by the backside surface of the electronic component and the first portion the lateral surface of the encapsulant is less than 90 degrees.

12. The package structure as claimed in claim 11, wherein the electronic component comprises a microstructure on the backside surface and contacting the encapsulant.

13. The package structure as claimed in claim 11, wherein the encapsulant comprises a body portion having the second portion of the lateral surface and a first protrusion protruding toward a first lateral surface of the electronic component.

14. The package structure as claimed in claim 13, wherein the first protrusion has a first lateral surface substantially aligned with the first lateral surface of the electronic component.

15. A package structure, comprising:
a substrate;
an electronic component disposed over the substrate and having an active surface, a backside surface opposite to the active surface, and a lateral surface extending between the active surface and the backside surface;
a warpage control element adhered to the backside surface of the electronic component and configured to reduce a warpage of the package structure; and
a protective element encapsulating the electronic component and the warpage control element.

16. The package structure as claimed in claim 15, wherein a first angle defined by the active surface and the lateral surface of the electronic component is 80 degrees to 100 degrees.

17. The package structure as claimed in claim 15, further comprising a redistribution layer (RDL) connected to the active surface of the electronic component, wherein the warpage control element is configured to reduce a warpage resulted from an asymmetric wiring structure of the RDL.

18. The package structure as claimed in claim 15, wherein the protective element contacts a lower portion of a lateral surface of the warpage control element and exposes an upper portion of the lateral surface of the warpage control element.

19. The package structure as claimed in claim 16, wherein a second angle defined by the backside surface of the electronic component and a lateral surface of the warpage control element is smaller than the first angle.

20. The package structure as claimed in claim 15, wherein the warpage control element comprises a body portion and a protrusion protruding toward the lateral surface of the electronic component, and a thickness of the body portion is greater than a thickness of the protrusion.
